(19) United States
(12) Patent Application Publication
(10) Pub. No.: US 2016/0225480 A1
(43) Pub. Date: Aug. 4, 2016

(54) CONDUCTIVE POLYMER FILM

(71) Applicant: LG CHEM, LTD., Seoul (KR)

(72) Inventor: Mi Kyoung KIM, Daejeon (KR)

(21) Appl. No.: 14/916,105

(22) PCT Filed: Dec. 23, 2014
(86) PCT No.: PCT/KR2014/012725

§ 371 Date: Mar. 2, 2016

(30) Foreign Application Priority Data
Dec. 23, 2013 (KR) 10-2013-0161746

(51) Int. Cl. H01B 1/12; H01L 51/44; H01L 51/00; H01L 51/52

(52) U.S. Cl. CPC H01B 1/124; H01L 51/5215; H01L 51/5234; H01L 51/442; H01L 51/0097

(57) ABSTRACT

The present application relates to a conductive polymer film having excellent coating properties with respect to a hydrophobic organic material and electrical conductivity, and more specifically, to a conductive polymer film including a conductive polymer layer; and a coating layer formed on the conductive polymer layer and including a surfactant having a hydrophile-lipophile balance (HLB) of 10 or more, polyethylene glycol, or a combination thereof.

### TECHNICAL FIELD

The present application relates to a transparent conductive polymer film, and a transparent electrode substrate and device including the same, and more specifically, to the conductive polymer film having high conductivity and excellent coating properties with respect to a hydrophobic organic material, and the transparent electrode substrate and device including the same.

### BACKGROUND

Transparent electrodes which are transparent and have conductivity are widely applied in display devices such as a liquid crystal display device, an organic light emitting device or the like, or solar cells, etc. The material which is most typically used in the transparent electrode currently is an indium tin oxide (ITO) film. However, the ITO film is formed through high temperature vacuum deposition, and thus a substrate having high heat resistance such as a glass substrate is required to form the ITO film, and a film-forming area, thickness or the like are also limited. Further, the ITO film itself is brittle, easily peeled upon bending, and thus unsuitable to be applied in a flexible substrate, etc.

Accordingly, the research to produce the transparent electrode using a conductive polymer instead of the ITO film has been increasingly performed recently. The conductive polymer may form a film at a low temperature, and thus is advantageous in that the substrate is less limited and a large-area film may be formed rapidly through a solution process. Currently, the transparent electrode using the conductive polymer is produced using a method of coating or printing a conductive polymer ink composition prepared by dispersing the conductive polymer in an aqueous solution on the substrate.

Further, poly(3,4-ethylenedioxythiophene) (PEDOT) is mainly used as the conductive polymer to form the transparent electrode, and PEDOT is insoluble in a solvent on its own. Accordingly, most conductive polymer ink compositions are prepared by doping PEDOT with polystyrene sulfonate (PSS) and dispersing in an aqueous solution before use. The conventional conductive polymer ink composition as described above exhibits high hydrophobicity. Further, recently, there have been many cases in which a polar solvent such as dimethyl sulfoxide (DMSO) or dimethyl formamide (DMF) has been added to the conductive polymer ink composition to increase conductivity, and in these cases, hydrophobicity of the conductive polymer ink composition has been further increased. However, the device such as the organic solar cell, the organic light emitting element, or the like is required to include a layer formed of a hydrophobic organic material such as a photoactive layer, a buffer layer, an insulating layer, or the like, but the hydrophobic organic layer is not coated well on the ink composition having high hydrophobicity as described above.

In order to resolve the issues as described above, the solution to improving coating properties with respect to the hydrophobic organic layer by adding a surfactant to the conductive polymer ink composition and increasing a surface energy of the ink film was proposed. However, when the surfactant was added to the conductive polymer ink composition as described above, conductivity is decreased due to the added surfactant, and thus it is difficult to realize high electrical conductivity, and particularly, storage stability of the ink is decreased, thus having a negative influence on electrical conductivity upon storage for the long term. Further, in order to obtain an effect of the surface energy improvement, a significant amount of the surfactant is required to be added, and at this time, the surfactant is not only dispersed on a surface of the conductive film, but also dispersed throughout an entire ink film after forming the film, as a result, the surfactant disrupts an electron transfer, and thereby acts as a factor of decreasing conductivity.

Accordingly, the development of conductive polymer film realizing high conductivity and having excellent coating properties with respect to the hydrophobic organic material is required.

### DESCRIPTION

### Technical Object

In order to resolve the above-described issue, the present application is directed to providing a transparent conductive polymer film having high conductivity and excellent coating properties with respect to a hydrophobic organic material, and a transparent electrode substrate and device including the same.

### Technical Solution

According to an aspect of the present application, there is provided a conductive polymer film including a conductive polymer layer; and a coating layer formed on the conductive polymer layer and including a surfactant having a hydrophile-lipophile balance (HLB) of 10 or more, polyethylene glycol, or a combination thereof.

According to another aspect of the present application, there is provided a transparent electrode substrate on which the conductive polymer film according to an embodiment of the present application is formed. Here, the electrode substrate may include a flexible substrate.

According to still another aspect of the present application, there is provided a device including the conductive polymer film according to the embodiment of the present application. Here, the device, for example, may be an organic light emitting device or an organic solar cell.

### Technical Effect

Since the conductive polymer film according to the embodiment of the present application has a high surface energy, and thus has high coating properties with respect to the hydrophobic organic material, the conductive polymer film according to the embodiment of the present application may be usefully applied to the transparent electrode substrate of the organic light emitting device or the organic solar cell to which a formation of the hydrophobic organic material layer such as a light-emitting layer or a photoactive layer is required.

Further, the conductive polymer film according to the embodiment of the present application may realize high conductivity by surface-treating the conductive ink layer, and thus may be usefully applied to products requiring for the high conductivity.

Further, the conductive polymer film according to the embodiment of the present application may be formed into a large area at a low temperature, and thus may be usefully applied to the flexible substrate, etc.

### EMBODIMENTS

Illustrative embodiments of the present application will be described in detail below with reference to the accompanying drawings. While the present application is shown and described in connection with illustrative embodiments thereof, it will be apparent to those skilled in the art that various modifications can be made without departing from the spirit and scope of the invention.

Hereinafter, illustrative embodiments of the present application will be described. However, the embodiments of the present application may be modified into a variety of different forms, and the scope of the present application is not limited to the embodiments which will be described below. Further, the embodiments of the present application are provided for the purpose of ease of description for those skilled in the art.

The present inventors have conducted extensive research to develop a conductive polymer film which does not decrease conductivity and may improve coating properties with respect to a hydrophobic organic material. As a result, the inventors have found that the above-described objective may be accomplished by forming a coating layer including a specific compound on a conductive polymer ink layer, and thereby the present application was completed.

More specifically, the conductive polymer film according to the embodiment of the present application includes a conductive polymer layer, and a coating layer formed on the conductive polymer layer and including a surfactant having a hydrophile-lipophile balance (HLB) of 10 or more, polyethylene glycol, and a combination thereof.

Here, the conductive polymer layer may be formed of a conductive polymer ink or the like which is generally produced and distributed in the related art, and the composition thereof is not particularly limited. For example, the conductive polymer ink may include an aqueous dispersion including a conductive polymer and a solvent, etc.

Further, any aqueous dispersion including a conductive polymer well-known in the related art may be used as the above-described aqueous dispersion including the conductive polymer without limitation, and a specific example of the aqueous dispersion may include a commercially available product such as PH-1000® made by Heraeus Holding GmbH, etc.

Further, the conductive polymer included in the aqueous dispersion may be a conductive polymer well-known in the related art, and for example, may be one or more types selected from the group consisting of conductive polymers such as polyacetylenes, polyphenylenevinylenes, polyaniline, polypyrrols, polythiophenes, and polythiophene vinylenes. In consideration of conductivity and heat stability, the conductive polymer is preferably poly(3,4-ethylenedioxythiophene):poly(styrene sulfonate) (PEDOT:PSS) or a derivative thereof.

Further, the solvent is to adjust viscosity, physical properties, or the like of the conductive polymer ink, any solvent capable of being well mixed with the conductive polymer may be used without limitation, and for example, may be a mixture of water and an organic solvent. Although a mixing ratio of the water and organic solvent is not particularly limited, in consideration of dispersibility and conductivity of the conductive polymer, the water and organic solvent may be mixed in a ratio of 10 to 150 parts by weight of the organic solvent with respect to 100 parts by weight of the water, or 25 to 100 parts by weight of the organic solvent with respect to 100 parts by weight of the water. In the present application, the unit “parts by weight” may denote, unless otherwise defined, a ratio of the weights. In another embodiment of the present application, the above-description mixing ratio of the water and organic solvent (water:organic solvent) may be in the range of 40:60 to 90:10 or 50:50 to 80:20 based on the weights.

Further, the conductive polymer ink may additionally include additives according to need, such as a conductivity enhancer, a surfactant, a polymer resin to improve humidity resistance or scratch resistance, etc.

As the conductivity enhancer, any conductivity enhancer well-known in the related art may be used without limitation, and for example, one or mixtures of dimethylsulfoxide (DMSO), N,N-dimethylformamide (DMF), tetrahydrofuran (THF), or the like may be used.

Examples of the surfactants may include a fluorine-based surfactant, a silicone-based surfactant, or other nonionic surfactants.

The conductive polymer layer is formed by coating or printing with the above-described conductive polymer ink. Here, the coating may be performed using a coating method which is generally used in the related art, such as a spin coating method, a bar coating method, a spray coating method or the like, and the printing described above may be performed using a general printing method used in the related field, a screen printing method, a gravure printing method, an inkjet printing method, etc.

Further, according to need, drying may be performed after coating or printing with the conductive polymer ink. Here, the drying described above may vary according to a type of the conductive polymer ink to be used, a thickness of the conductive polymer layer or the like, and for example, may be performed at a temperature in the range of about 60 to 180° C. for about 5 to 40 minutes.

Further, according to need, a surface treatment may be performed after forming the conductive polymer layer using the method as described above. Here, the surface treatment may be performed using a method of applying an acid solution or an organic solvent to the conductive polymer layer and performing a heat process thereon.

Examples of the acid solution may include, but are not limited to, for example, a p-toluene sulfonic acid solution, a sulfuric acid solution, a citric acid solution, combinations thereof, or the like, and a concentration of the acid solution is preferably in the range of about 0.01 to 3 molar concentration. Further, examples of the organic solvents may include, but are not limited to, for example, acetonitrile, methanol, ethanol, isopropyl alcohol, tetrahydofuran, ethylene glycol dimethyl sulfoxide, a combination thereof, etc.

Further, a method of applying the acid solution or the organic solvent is not particularly limited, and various application methods well-known in the related field such as a paint brushing method, a spray coating method, a doctor blade method, a dip drawing method, a spin coating method, an inkjet printing method, a slot die coating method or the like may be used without limitation.

Further, the heat process is preferably performed at a temperature in the range of about 100 to 170° C. for about 30 seconds to 15 minutes.

Further, a process for removing the acid solution remaining on the polymer conductive layer may be performed after the heat process, and more specifically, the process of removing the acid solution may be performed using a method of immersing the heat-treated polymer conductive layer into an alcohol solvent such as methanol, ethanol, isopropanol or the like, and then drying. Here, drying described above may be performed at a temperature in the range of about 40 to 170° C. for about 30 seconds to 20 minutes.

When the surface treatment as described above is performed, conductivity of the conductive polymer film may be significantly improved.

When the conductive polymer layer is formed using the method as described above, the coating layer including the surfactant having a hydrophile-lipophile balance (HLB) of 10 or more, polyethylene glycol, or a combination thereof is formed on the conductive polymer layer. In another embodiment of the present application, the HLB may be 11 or more, 12 or more, 13 or more, 14 or more, 15 or more, 16 or more, 17 or more, or 18 or more. Further, in another embodiment of the present application, the HLB may be 40 or less, 35 or less, 30 or less, 25 or less, or 20 or less.

Here, the HLB denotes a ratio between a hydrophilic part and a lipophilic part. The above-described HLB is determined according to a compound, and the ratio according to the compound is well known. The HLB may be calculated using an expression well-known in the related art, for example, using any one of the following Expressions 1 to 4. In general, the higher the value of the HLB is, the higher hydrophilicity is, and the lower the value of the HLB is, the higher lipophilicity is.

HLB=20×(molecular weight of hydrophilic group part/molecular weight of surfactant) [Expression 1]

Expression 1 was defined by Griffin, and is an expression in which the HLB of the general non-ionic surfactant may be found.

HLB=(wt % of hydrophilic group)/5 [Expression 2]

Expression 2 is an expression in which the HLB of a polyoxyethylene glycol-based surfactant may be calculated, and the HLB is calculated by substituting the wt % of the polyoxyethylene glycol part with the wt % of the hydrophilic group.

HLB=20×{1−(saponification value of a polyvalent alcohol ester)/(acid value of a fatty acid)} [Expression 3]

Expression 3 may be applied upon finding the HLB value of the polyvalent alcohol fatty acid ester-based surfactant.

HLB=(wt % of an oxyethylene chain+wt % of a polyvalent alcohol)/5 [Expression 4]

The HLB of the material which may not be hydrolyzed may be found using Expression 4.

The surfactant having the HLB of 10 or more is, for example, preferably a surfactant including structures of one or more types selected from the group consisting of a random copolymer of ethylene oxide and propylene oxide, a block copolymer of ethylene oxide and propylene oxide, an alkyl polyglycol ether, a polyoxyethylenealkylether, a polyoxyethylene fatty acid ester, a polyoxyethylenealkylphenolether, a sorbitan fatty acid ester, a polyoxyethylenesorbitan fatty acid ester, a sucrose fatty acid ester, an acetylene glycol, and a polyoxyethylene, but is not limited thereto.

Particularly, in the embodiment of the present application, it is more preferable that the surfactant having the HLB of 10 or more includes an acetylene glycol and/or polyoxyethylene structures.

More specifically, the surfactant including the acetylene glycol structure may be, for example, represented by the following Formula 1, and the surfactant including the polyoxyethylene structure may be, for example, represented by the following Formula 2.

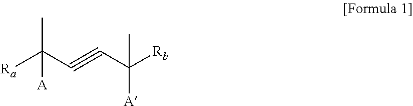

Here, Rₐ and R_{b} are respectively hydrogen or an alkyl group, A is —[OCH₂CH₂]ₘ—OH, A′ is —[OCH₂CH₂]ₙ—OH, and m and n are respectively integers in the range of 1 to 80.

In the present specification, the term “alkyl group” denotes, unless otherwise defined, an alkyl group having 1 to 20 carbon atoms, 1 to 16 carbon atoms, 1 to 12 carbon atoms, 1 to 8 carbon atoms, or 1 to 4 carbon atoms. The alkyl group may be in a straight chain, branched chain or ring shape, and may be arbitrarily substituted by one or more substituents.

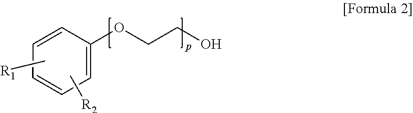

Here, R₁ and R₂ are hydrogen or an alkyl group, respectively, at least one of R₁ and R₂ is an alkyl group, and p is an integer in the range of 1 to 200.

Further, in the embodiment of the present application, a commercially available product may be used as the surfactant including the acetylene glycol structure, and for example, may be one or more selected from the group consisting of Surfynol 420® Surfynol 465®, Surfynol 485®, Surfynol 104E®, and Dynol 604® (Air Products and Chemicals, Inc)., but is not limited thereto.

Further, a commercially available product may be used as the surfactant including the polyoxyethylene structure, and for example, may be one or more selected from the group consisting of IGEPAL CO-630®, IGEPAL CO-890®, and IGEPAL DM-970® (Sigma-Aldrich Corporation), but is not limited thereto.

Further, the polyethylene glycol is preferably an oligomer or a polymer having a number average molecular weight of 20,000 or less, more preferably, the oligomer or polymer having a number average molecular weight in the range of about 200 to 10,000, and most preferably, the oligomer or polymer having a number average molecular weight in the range of about 200 to 2,000.

Further, in the embodiment of the present application, the coating layer may include only one of the surfactant having the HLB of 10 or more or the polyethylene glycol, and may include both of the surfactant having the HLB of 10 or more and the polyethylene glycol.

When the polyethylene glycol and the surfactant are used together, it is advantageous in that coating properties with respect to the organic solution are further improved, but electrical conductivity is slightly decreased as compared to the case in which only one type of the polyethylene glycol and the surfactant is used. Accordingly, it is preferable to suitably select and use the composition of the coating layer in consideration of the use of the conductive polymer film, etc.

Further, when the polyethylene glycol and the surfactant having the HLB of 10 or more are mixed and used, as a weight ratio of the polyethylene glycol and the surfactant included in the coating layer, 5 to 100 parts by weight of the surfactant may be included in the coating layer with respect to 100 parts by weight of the polyethylene glycol.

Further, the coating layer may be formed of a coating solution prepared by dissolving the surfactant having the HLB of 10 or more and/or the polyethylene glycol in the organic solvent. Here, any organic solvent capable of dissolving the surfactant or polyethylene glycol may be used without particular limitation, and for example, an organic solvent alcohol such as methanol, ethanol, and isopropanol; ketones such as acetone and methyl ethyl ketone; or mixed solvents thereof may be used.

Further, the coating solution may include at least one of the surfactant and the polyethylene glycol at content in an approximate range of 0.2 to 10 wt %, for example, 0.3 to 8 wt %, or 0.5 to 5 wt %. When a concentration of the coating solution satisfies the above-described value range, an enhanced effect of coating properties with respect to the organic material may be obtained without affecting physical properties of an applied element.

Further, the coating layer may be formed using a method of forming a coating layer which is well-known in the related field, such as a paint brushing method, a spray coating method, a doctor blade method, a dip drawing method, a spin coating method, an inkjet printing method, a slot die coating method, etc. After the coating layer is formed using the above-described method, drying may be performed to remove the solvent, and here, the drying temperature varies according to the solvent to be used, for example, may be in the range of about 60 to 80° C.

Further, a thickness of the coating layer may be, but is not limited to, 1 μm or less, for example, in an approximate range of about 1 nm to 1 μm, 1 nm to 800 nm, or 1 to 500 nm. This is because, when the thickness of the coating layer is greater than 1 μm, the coating layer acts as an insulating layer, and thus has a negative influence on electrical conductivity of the conductive film.

According to the research of the present inventor, as described above, when the coating layer including the surfactant having the hydrophile-lipophile balance (HLB) of 10 or more, the polyethylene glycol, or a combination thereof is formed on the conductive polymer layer, it was determined that coating properties with respect to a hydrophobic organic material may be improved and high conductivity may be realized.

More specifically, the conductive polymer film according to the embodiment of the present application had a surface energy of 50 mN/m or more, more specifically, in the range of about 55 to 85 mN/m, and had a contact angle with respect to o-dichlorobenzene of 30 degrees or less, more specifically, in the range of about 1 to 25 degrees. As described above, since the conductive polymer film according to the embodiment of the present application has a high surface energy and a small contact angle with respect to the organic solvent, the conductive polymer film has excellent coating properties with respect to a hydrophobic organic layer.

Further, the conductive polymer film according to the embodiment of the present application had a water contact angle of 30 degrees or less, and more specifically, in the range of about 10 to 26 degrees.

The surface energy and contact angle may be values measured at room temperature, and accordingly, for example, may be values measured at a temperature of about 23° C. or about 25° C.

As described above, the conductive polymer film according to the embodiment of the present application has excellent coating properties with respect to the hydrophobic organic material and electrical conductivity, and thus may be usefully used as a transparent electrode, a buffer layer or the like in devices in which hydrophobic organic layers are laminated, such as an organic light emitting element or an organic solar cell.

Further, the conductive polymer film according to the embodiment of the present application may be applied onto the substrate and may be usefully used as the transparent electrode substrate. Here, a type of the substrate is not particularly limited, and the conductive polymer film may be suitably applied onto a glass substrate or a polymer substrate. As described above, the transparent electrode substrate having at least one surface on which the conductive polymer film according to the embodiment of the present application is formed may be applied to various devices, and particularly, may be usefully used in the organic light emitting device, the organic solar cell, etc.

Further, the transparent electrode substrate in which the conductive polymer film of the embodiment of the present application is applied onto the polymer substrate or thin-type glass substrate may be usefully used as a flexible substrate.

Hereinafter, the present application will be described in greater detail in conjunction with specific examples.

### Preparation Example 1

### Conductive Polymer Ink A

After 2.5 g of deionized water, 1 g of diethylene glycol monobutylether and 1.5 g of propylene glycol were added to 5 g of a PEDOT:PSS aqueous dispersion (Clevios™ PH-1000), 0.018 g of F-555 which is a fluorine-based surfactant was further added thereto, stirred for 2 hours, and thereby a conductive polymer ink A was prepared.

### Preparation Example 2

### Conductive Polymer Ink B

After 2.5 g of deionized water, 1 g of diethylene glycol monobutylether, and 1.5 g of propylene glycol were added into 5 g of a PEDOT:PSS aqueous dispersion (PH-1000; manufactured by Heraeus Holding GmbH), 0.018 g of F-555 which is a fluorine-based surfactant and 0.1 g of Igepal® DM-970 were also added thereto, stirred for 2 hours, and thereby a conductive polymer ink B was prepared.

### Example 1

After the conductive polymer ink A prepared by Preparation Example 1 was spin-coated on a glass substrate having a width of 5 cm and a length of 5 cm at 800 rpm for 9 seconds, the coating layer was dried for 30 minutes on a hot plate at 120° C., and thereby a conductive polymer layer was formed.

The conductive polymer layer was treated with an application of a p-toluene sulfonic acid aqueous solution having a concentration of 0.16 M, and then treated with heat at 160° C. for 5 minutes. Thereafter, the conductive polymer layer was immersed in a methanol solution including 1 wt % of Igepal® DM-970 at room temperature, taken out therefrom, dried for 10 minutes on the hot plate at 80° C., and thereby a conductive polymer film including the conductive polymer layer and a coating layer formed thereon was prepared.

### Example 2

The conductive polymer film was prepared in the same manner as in Example 1 except that the glass substrate on which the surface-treated conductive polymer layer was formed was immersed in the methanol solution including 0.5 wt % of Igepal® DM-970 and 1 wt % of polyethylene glycol.

### Example 3

The conductive polymer film was prepared in the same manner as in Example 1 except that the glass substrate on which the surface-treated conductive polymer layer was formed was immersed in the methanol solution including 5 wt % of the polyethylene glycol.

### Example 4

The conductive polymer film was prepared in the same manner as in Example 1 except that the glass substrate on which the surface-treated conductive polymer layer was formed was immersed in the methanol solution including 0.5 wt % of Igepal® DM-970 and 5 wt % of the polyethylene glycol.

### Comparative Example 1

The conductive polymer film was prepared in the same manner as in Example 1 except that the coating layer was not formed on the surface-treated conductive polymer layer.

### Comparative Example 2

The conductive polymer film was prepared in the same manner as in Example 1 except that the glass substrate on which the surface-treated conductive polymer layer was formed was immersed in methanol.

### Comparative Example 3

After the conductive polymer ink B prepared by Preparation Example 2 was spin-coated on the glass substrate having a width of 5 cm and a length of 5 cm at 800 rpm for 9 seconds, the coating layer was dried for 30 minutes on the hot plate at 120° C., and thereby the conductive polymer layer was formed.

### Comparative Example 4

The conductive polymer film prepared by Comparative Example 3 was treated with an application of the p-toluene sulfonic acid aqueous solution having a concentration of 0.16 M, and then treated with heat at 160° C. for 5 minutes. Thereafter, the conductive polymer layer was immersed in methanol for 5 minutes at room temperature to remove the p-toluene sulfonic acid aqueous solution remaining on the surface thereof, dried again at 160° C. for 5 minutes to remove the solvent of methanol, and thereby the surface-treated conductive polymer film was prepared.

### Experimental Example

A contact angle and sheet resistance with respect to an organic solvent of the surface of the conductive polymer films prepared in Examples 1 to 4 and Comparative Examples 1 to 4 were measured. The measurement of the contact angle and sheet resistance was performed using a well-known method.

The contact angle with respect to the organic solvent was measured by dropping an o-dichlorobenzene solution as the organic solvent onto the surface of the conductive polymer film, and DSA 100 (manufactured by KRÜSS GmbH) was used as a measurement device.

The sheet resistance was measured using a 4-point probe, and MCP-T600 (manufactured by Mitsubishi Chemical Corporation) was used as a measurement device.

The result of the measurement was shown in the following Table 1.

TABLE 1

| | Contact angle | Sheet resistance |
|---|---|---|
| | (unit: degrees) | (unit: Ω/sq) |
| Example1 | 16.3 | 199 |
| Example 2 | 12.4 | 228 |
| Example 3 | 16.0 | 205 |
| Example 4 | 6.3 | 232 |
| Comparative Example 1 | 59.6 | 225 |
| Comparative Example 2 | 52.2 | 234 |
| Comparative Example 3 | 18.9 | 522 |
| Comparative Example 4 | 60.8 | 224 |

As shown in Table 1, it may be determined that the conductive polymer films of the according to the embodiment of the present application which were prepared in Examples 1 to 4 have excellent coating properties with respect to the organic layer and electrical conductivity because the conductive polymer films have a low contact angle in the range of 6.3 to 16.3 degrees with respect to the organic solvent, and also have a low sheet resistance in the range of about 199 to 232 Ω/sq.

On the other hand, in Comparative Examples 1 and 2, it may be determined that electrical conductivity of the conductive polymer films is excellent, but coating properties with respect to the organic layer are poor because the contact angle with respect to the organic solvent is high. Further, in Comparative Example 3 in which the surfactant having the HLB of 10 or more was added into the conductive ink composition, it may be determined that coating properties with respect to the organic layer are high, but electrical conductivity is poor. Further, in Comparative Example 4 in which the conductive polymer film prepared in Comparative Example 3 was surface-treated, it may be determined that electrical conductivity is improved due to the surface treatment, but the contact angle with respect to the organic solvent increases, thereby degrading coating properties.

1. A conductive polymer film, comprising:
a conductive polymer layer; and
a coating layer formed on the conductive polymer layer and including one or more selected from the group consisting of a surfactant having a hydrophile-lipophile balance (HLB) of 10 or more and polyethylene glycol.

2. The conductive polymer film of claim 1, wherein the conductive polymer film has a surface energy of 50 mN/m or more.

3. The conductive polymer film of claim 1, wherein the conductive polymer film has a water contact angle of 30 degrees or less.

4. The conductive polymer film of claim 1, wherein the conductive polymer film has a contact angle of 30 degrees or less with respect to o-dichlorobenzene.

5. The conductive polymer film of claim 1, wherein the conductive polymer layer is surface-treated by heating after coating an acid solution or an organic solvent.

6. The conductive polymer film of claim 5, wherein the acid solution is a p-toluene sulfonic acid solution, a sulfuric acid solution, a citric acid solution, or a combination thereof.

7. The conductive polymer film of claim 5, wherein the organic solvent is acetonitrile, methanol, ethanol, isopropyl alcohol, tetrahydofuran, ethylene glycol, dimethyl sulfoxide, or a combination thereof.

8. The conductive polymer film of claim 5, wherein the surface treatment is performed at a temperature in a range of 100 to 170° C.

9. The conductive polymer film of claim 1, wherein the coating layer is formed of a coating solution including at least one of the surfactant and polyethylene glycol, and an alcohol solvent.

10. he conductive polymer film of claim 9, wherein the coating solution includes at least one of the surfactant and polyethylene glycol at content in a range of 0.2 to 10 wt %.

11. The conductive polymer film of claim 1, wherein the surfactant having a hydrophile-lipophile balance (HLB) of 10 or more includes structures of one or more types selected from the group consisting of a random copolymer of ethylene oxide and propylene oxide, a block copolymer of ethylene oxide and propylene oxide, an alkyl polyglycol ether, a polyoxyethylenealkylether, a polyoxyethylene fatty acid ester, a polyoxyethylenealkylphenolether, a sorbitan fatty acid ester, polyoxyethylenesorbitan fatty acid ester, a sucrose fatty acid ester, acetylene glycol, and polyoxyethylene.

12. The conductive polymer film of claim 11, wherein the surfactant including the acetylene glycol structure comprises a compound represented by the following Formula 1: 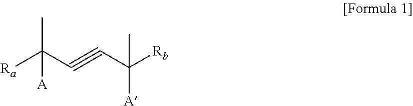
where, in Formula 1, Rₐ and R_{b} are respectively hydrogen or an alkyl group, A is —[OCH₂CH₂]ₘ—OH, A′ is —[OCH₂CH₂]ₙ—OH, and m and n are respectively integers in a range of 1 to 80.

13. The conductive polymer film of claim 11, wherein the surfactant including the polyoxyethylene structure comprises a compound represented by the following Formula 2: 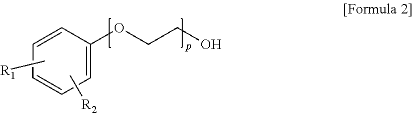
where, in Formula 2, R₁ and R₂ are respectively hydrogen or an alkyl group, at least one of R₁ and R₂ is an alkyl group, and p is an integer in a range of 1 to 200.

14. The conductive polymer film of claim 1, wherein the coating layer has a thickness in a range of 1 nm to 1 μm.

15. A transparent electrode substrate having at least one surface on which the conductive polymer film of claim 1 is formed.

16. The transparent electrode substrate of claim 15, wherein the transparent electrode substrate is a flexible substrate.

17. A device comprising the conductive polymer film of claim 1.

18. The device of claim 17, wherein the device is an organic light emitting device or an organic solar cell.
